(19) United States
(12) Patent Application Publication
(10) Pub. No.: US 2025/0158600 A1
(43) Pub. Date: May 15, 2025

(54) DYNAMIC D FLIP-FLOP, DATA OPERATION UNIT, CHIP, HASH BOARD AND COMPUTING DEVICE

(71) Applicant: CANAAN CREATIVE (SH) CO., LTD., Shanghai (CN)

(72) Inventors: Shuangwen CHEN, Beijing (CN); Zhi LI, Shanghai (CN); Nangeng ZHANG, Beijing (CN)

(21) Appl. No.: 19/020,207

(22) Filed: Jan. 14, 2025

Related U.S. Application Data
(63) Continuation of application No. PCT/CN2023/093277, filed on May 10, 2023.

(30) Foreign Application Priority Data
Jul. 14, 2022 (CN) 202210829816.X

(51) Int. Cl. H03K 3/356; G06F 1/04

(52) U.S. Cl. CPC H03K 3/356113; G06F 1/04

(57) ABSTRACT

The invention provides a dynamic D flip-flop (100), comprising: an input terminal (D), an output terminal (Q), a clock signal terminal (CLK1, CLK2), a first latch unit (101), a second latch unit (102), an output drive unit (103); the first latch unit (101), the second latch unit (102), and the output drive unit (103) are sequentially connected in series between the input terminal (D) and the output terminal (Q); a first node (S0) is provided between the first latch unit (101) and the second latch unit (102), and a second node (S1) is provided between the second latch unit (102) and the output drive unit (103); wherein, further comprising a data retention unit (104) electrically connected to the first node (S0) and/or the second node (S1). The data retention time can be effectively increased and the security and accuracy of data can be improved.

### CROSS-REFERENCES TO RELATED APPLICATION

This application is a continuation of International Application No. PCT/CN2023/093277, filed on May 10, 2023, which claims priority to Chinese Patent Application No. CN202210829816.X, filed with the China National Intellectual Property Administration on Jul. 14, 2022, both of which are hereby incorporated by reference in their entirety.

### TECHNICAL FIELD

The invention relates to a clock-controlled storage device, and particularly to a register, an operation unit, a chip, and a computing device applied to large-scale data operating equipment.

### BACKGROUND

Dynamic flip-flops are widely applied, and may be used for registering of digital signals. In the existing dynamic flip-flop, the transmitted data are often temporarily stored in a parasitic capacitance generated by transistors constituting a latch unit. However, since the operation frequency is gradually improved, the temporarily stored data easily generate dynamic leakage current, causing insufficient data retention time, and leading to data loss and reducing accuracy of operation.

Therefore, how to effectively improve data retention time in the dynamic flip-flop is actually the problem to be solved.

### SUMMARY

To solve the above problem, the invention provides a dynamic D flip-flop capable of effectively increasing data retention time, and improving security and accuracy of data.

To achieve the object, the invention provides a dynamic D flip-flop, comprising: an input terminal for inputting a first data; an output terminal for outputting a second data; a clock signal terminal for supplying a clock signal; a first latch unit for transmitting a data at the input terminal and latching the first data under control of the clock signal; a second latch unit for latching the data transmitted by the first latch unit; an output drive unit for outputting the data received from the second latch unit; the first latch unit, the second latch unit, and the output drive unit are sequentially connected in series between the input terminal and the output terminal; and a first node is provided between the first latch unit and the second latch unit, and a second node is provided between the second latch unit and the output drive unit; wherein, further comprising a data retention unit electrically connected to the first node and/or the second node, the data retention unit is configured for assisting in storing the data latched at the first node and/or the second node.

In the dynamic D flip-flop, the data retention unit has a first terminal electrically connected to the first node, and a second terminal electrically connected to the second node.

In the dynamic D flip-flop, the data retention unit comprises a PMOS transistor and/or a NMOS transistor.

In the dynamic D flip-flop, the PMOS transistor has a source terminal electrically connected to the first node or the second node, a drain terminal electrically connected to the second node or the first node, and a gate terminal electrically connected to a power supply.

In the dynamic D flip-flop, the NMOS transistor has a source terminal electrically connected to the first node or the second node, a drain terminal electrically connected to the second node or the first node, and a gate terminal electrically connected to a ground.

In the dynamic D flip-flop, the PMOS transistor has a source terminal, a drain terminal and a gate terminal, the source terminal and the drain terminal of the PMOS transistor are electrically connected to the first node or the second node, and the gate terminal of the PMOS transistor is electrically connected to the second node or the first node.

In the dynamic D flip-flop, the NMOS transistor has a source terminal, a drain terminal and a gate terminal, the source terminal and the drain terminal of the NMOS transistor are electrically connected to the first node or the second node, and the gate terminal of the NMOS transistor is electrically connected to the second node or the first node.

In the dynamic D flip-flop, the data retention unit is electrically connected to the first node or the second node, and the data retention unit comprises a PMOS transistor and/or a NMOS transistor.

In the dynamic D flip-flop, the PMOS transistor has a source terminal, a drain terminal and a gate terminal, the source terminal and the drain terminal of the PMOS transistor are electrically connected to the first node, and the gate terminal of the PMOS transistor is electrically connected to a power supply.

In the dynamic D flip-flop, the NMOS transistor has a source terminal, a drain terminal and a gate terminal, the source terminal and the drain terminal of the NMOS transistor are electrically connected to the first node, and the gate terminal of the NMOS transistor is electrically connected to a ground.

In the dynamic D flip-flop, the PMOS transistor has a source terminal, a drain terminal and a gate terminal, the source terminal and the drain terminal of the PMOS transistor are electrically connected to a power supply, and the gate terminal of the PMOS transistor is electrically connected to the first node.

In the dynamic D flip-flop, the NMOS transistor has a source terminal, a drain terminal and a gate terminal, the source terminal and the drain terminal of the NMOS transistor are electrically connected to a ground, and the gate terminal of the NMOS transistor is electrically connected to the first node.

In the dynamic D flip-flop, the PMOS transistor has a source terminal, a drain terminal and a gate terminal, the source terminal and the gate terminal of the PMOS transistor are electrically connected to a power supply, and the drain terminal of the PMOS transistor is electrically connected to the first node.

In the dynamic D flip-flop, the NMOS transistor has a source terminal, a drain terminal and a gate terminal, the source terminal and the gate terminal of the NMOS transistor are electrically connected to a ground, and the drain terminal of the NMOS transistor is electrically connected to the first node.

In the dynamic D flip-flop, the PMOS transistor has a source terminal, a drain terminal and a gate terminal, the source terminal and the drain terminal of the PMOS transistor are electrically connected to the second node, and the gate terminal of the PMOS transistor is electrically connected to a power supply.

In the dynamic D flip-flop, the NMOS transistor has a source terminal, a drain terminal and a gate terminal, the source terminal and the drain terminal of the NMOS transistor are electrically connected to the second node, and the gate terminal of the NMOS transistor is electrically connected to a ground.

In the dynamic D flip-flop, the PMOS transistor has a source terminal, a drain terminal and a gate terminal, the source terminal and the drain terminal of the PMOS transistor are electrically connected to a power supply, and the gate terminal of the PMOS transistor is electrically connected to the second node.

In the dynamic D flip-flop, the NMOS transistor has a source terminal, a drain terminal and a gate terminal, the source terminal and the drain terminal of the NMOS transistor are electrically connected to a ground, and the gate terminal of the NMOS transistor is electrically connected to the second node.

In the dynamic D flip-flop, the PMOS transistor has a source terminal, a drain terminal and a gate terminal, the source terminal and the gate terminal of the PMOS transistor are electrically connected to a power supply, and the drain terminal of the PMOS transistor is electrically connected to the second node.

In the dynamic D flip-flop, the NMOS transistor has a source terminal, a drain terminal and a gate terminal, the source terminal and the gate terminal of the NMOS transistor are electrically connected to a ground, and the drain terminal of the NMOS transistor is electrically connected to the second node.

In the dynamic D flip-flop, the clock signal comprises a first clock signal and a second clock signal in a opposite phase.

In the dynamic D flip-flop, the first latch unit is a transmission gate.

In the dynamic D flip-flop, the transmission gate comprises a PMOS transistor and a NMOS transistor connected in parallel, a gate terminal of the PMOS transistor is electrically connected to the first clock signal, and a gate terminal of the NMOS transistor is electrically connected to the second clock signal.

In the dynamic D flip-flop, the second latch unit is a three-state inverter.

In the dynamic D flip-flop, the three-state inverter comprises a first PMOS transistor, a second PMOS transistor, a first NMOS transistor and a second NMOS transistor connected in series, gate terminals of the first PMOS transistor and the second NMOS transistor are electrically connected as an input terminal of the three-state inverter, a gate terminal of the second PMOS transistor is electrically connected to the second clock signal, and a gate terminal of the first NMOS transistor is electrically connected to the first clock signal.

In the dynamic D flip-flop, the output drive unit is an inverter.

In the dynamic D flip-flop, the inverter comprises a PMOS transistor and a NMOS transistor connected in series.

The dynamic D flip-flop in the invention can effectively increase data retention time, and improve security and accuracy of data.

To better achieve the object, the invention further provides a data operation unit, comprising a control circuit, an operational circuit and a plurality of dynamic D flip-flops interconnected with each other, the plurality of dynamic D flip-flops are connected in series and/or in parallel; wherein, the plurality of dynamic D flip-flops are any one of the dynamic D flip-flop.

To better achieve the object, the invention further provides a chip, comprising at least one of the data operation unit.

To better achieve the object, the invention further provides a hash board for a computing device, comprising at least one of the chip.

To better achieve the object, the invention further provides a computing device, comprising a power supply board, a control board, a connection board, a radiator and a plurality of hash boards, the control board is connected to the hash boards through the connection board, the radiator is disposed around the hash boards, the power supply board is configured to supply a power supply to the connection board, the control board, the radiator and the hash boards, wherein the hash boards are any one of the hash board.

Hereinafter, the invention will be described in detail with reference to the accompanying drawings and the detailed embodiments, but the invention is not limited thereto.

### BRIEF DESCRIPTION OF THE DRAWINGS

FIG. 1 is a schematic diagram of a circuit of a dynamic D flip-flop in one embodiment of the invention.

FIG. 2 is a schematic diagram of a circuit of a dynamic D flip-flop in another embodiment of the invention.

FIG. 3 is a schematic diagram of a circuit of a dynamic D flip-flop in still another embodiment of the invention.

FIG. 4 is a schematic diagram of a circuit of a dynamic D flip-flop in yet another embodiment of the invention.

FIG. 5 is a schematic diagram of a circuit of a dynamic D flip-flop in an extended embodiment of the invention.

FIG. 6 is a schematic diagram of a data operation unit of the invention.

FIG. 7 is a schematic diagram of a chip of the invention.

FIG. 8 is a schematic diagram of a hash board of the invention.

FIG. 9 is a schematic diagram of a computing device of the invention.

In the figures, reference signs are as follows:

100: dynamic D flip-flop
101: first latch unit
102: second latch unit
102P1: first PMOS transistor
102P2: second PMOS transistor
102N1: first NMOS transistor
102N2: second NMOS transistor
103: output drive unit
104: data retention unit
   104P: PMOS transistor
   104N: NMOS transistor
800: data operation unit
801: control circuit
802: operational circuit
900: chip
901: control unit
1000: hash board
1100: computing device
1101: connection board
1102: control board
1103: radiator
1104: power supply board
D: input terminal
Q: output terminal
CLK1: first clock signal terminal
CLK2: second clock signal terminal
CKP, CKN: clock signal
S0: first node
S1: second node

### DETAILED DESCRIPTION

Hereinafter structure principle and working principle of the invention are described in details with reference to the accompanying drawings:

Specific terms are used in the specification and subsequent claims to refer to specific components. Those skilled in the art shall understand that manufacturers may use different terms to name the same component. The specification and subsequent claims distinguish components from each other by different functions of the components, instead of different names.

“Comprise” and “include” mentioned in the whole specification and subsequent claims are open words, and shall be interpreted as “include but not limited to”. Moreover, the word “connection” herein includes any direct and indirect electrical connection means. The indirect electrical connection means comprises connecting through other devices.

### Embodiment One

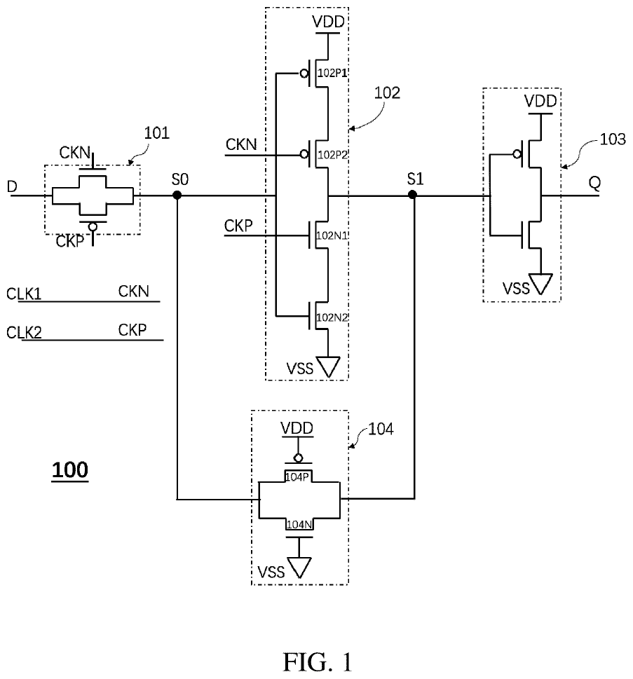

FIG. 1 is a schematic diagram of a circuit of a dynamic D flip-flop in one embodiment of the invention. As shown in FIG. 1, the dynamic D flip-flop 100 comprises an input terminal D, an output terminal Q, a first clock signal terminal CLK1, a second clock signal terminal CLK2, a first latch unit 101, a second latch unit 102, an output drive unit 103 and a data retention unit 104. The first latch unit 101, the second latch unit 102, and the output drive unit 103 are sequentially connected in series between the input terminal D and the output terminal Q, a first node S0 is formed between the first latch unit 101 and the second latch unit 102, and a second node S1 is formed between the second latch unit 102 and the output drive unit 103. The data retention unit 104 is electrically connected between the first node S0 and the second node S1. In the dynamic D flip-flop 100, the input terminal D is configured for inputting data that need to be transmitted from the outside to the dynamic D flip-flop 100, the output terminal Q is configured for outputting the data that need to be transmitted from the dynamic D flip-flop 100 to the outside, and the first clock signal terminal CLK1 and the second clock signal terminal CLK2 are configured for supplying a clock control signal to the dynamic D flip-flop 100, and the clock control signal comprises a clock signal CKN and a clock signal CKP configured to control on and off of the first latch unit 101 and the second latch unit 102. The clock signal CKN and the clock signal CKP are inverted clock signals, and the first latch unit 101 and the second latch unit 102 will not turn on or turn off at the same time.

Specifically, as shown in FIG. 1, the first latch unit 101 of the dynamic D flip-flop 100 is a transmission gate structure, and the first latch unit 101 comprises a PMOS transistor and a NMOS transistor connected in parallel. One terminal of the first latch unit 101 is electrically connected to the input terminal D, and the other terminal of the first latch unit 101 is electrically connected to the first node S0. In the first latch unit 101, a gate terminal of the NMOS transistor is electrically connected to the clock signal CKN, and a gate terminal of the PMOS transistor is electrically connected to the clock signal CKP. When CKP is at a low level, CKN is at a high level, the PMOS transistor and the NMOS transistor of the first latch unit 101 are both in a turn-on state, and the input terminal D transmits the data that need to be transmitted to the first node S0 through the first latch unit 101. When CKP is at a high level, CKN is at a low level, the PMOS transistor and the NMOS transistor of the first latch unit 101 are both in a turn-off state, the data at the input terminal D cannot be transmitted to the first node S0 through the first latch unit 101, and the first latch unit 101 latches the data transmitted to the first node S0 in the previous time period. In this embodiment, the first latch unit 101 takes the transmission gate structure as an example. Of course, the first latch unit 101 can also be other forms of analog switch units such as a three-state inverter, only if the switch function can be achieved under control of the clock signal, but the invention is not limited thereto.

Please continue to refer to FIG. 1. the second latch unit 102 of the dynamic D flip-flop 100 is a three-state inverter structure, and the second latch unit 102 comprises a first PMOS transistor 102P1, a second PMOS transistor 102P2, a first NMOS transistor 102N1 and a second NMOS transistor 102N2 connected in series between a power supply VDD and a ground VSS. Gate terminals of the first PMOS transistor 102P1 and the second NMOS transistor 102N2 are connected as an input terminal of the second latch unit 102 and electrically connected to the first node S0. Drain terminals of the second PMOS transistor 102P2 and the first NMOS transistor 102Nl are connected as an output terminal of the second latch unit 102 and electrically connected to the second node S1. A source terminal of the first PMOS transistor 102P1 is connected to the power supply VDD and a source terminal of the second NMOS transistor 102N2 is connected to the ground VSS.

In this embodiment, a gate terminal of the second PMOS transistor 102P2 is under control of the clock signal CKN and a gate terminal of the first NMOS transistor 102N1 is under control of the clock signal CKP as clock control terminals of the second latch unit 102. Of course, it can also be that the gate terminal of the first PMOS transistor 102P1 is under control of the clock signal CKN, the gate terminal of the second NMOS transistor 102N2 is under control of the clock signal CKP, and the gate terminals of the second PMOS transistor 102P2 and the first NMOS transistor 102Nl are connected as the input terminal of the second latch unit 102. The invention is not limited thereto.

Specifically, as shown in FIG. 1, when CKP is at a low level, CKN is at a high level, the second PMOS transistor 102P2 and the first NMOS transistor 102N1 are both in a turn-off state, and the second latch unit 102 is in a high impedance state. The data at the first node S0 cannot be transmitted to the second node S1 through the second latch unit 102, the data at the first node S0 is latched to maintain an original state and the function of data registering is achieved.

When CKP is at a high level, CKN is at a low level, the second PMOS transistor 102P2 and the first NMOS transistor 102N1 are both in a turn-on state, the second latch unit 102 inverts the data at the first node S0 and then transmits the data to the second node S1. The data is outputted to the output drive unit 103 and transmitted to the output terminal Q by the output drive unit 103 to rewrite the data at the output terminal Q.

As shown in FIG. 1, the output drive unit 103 of the dynamic D flip-flop 100 is an inverter structure, the output drive unit 103 further inverts the data received from the second latch unit 102 to form data having the same phase as the data at the input terminal D, and output the data through the output terminal Q. Meanwhile, the output drive unit also can improve driving capability of the data.

The dynamic D flip-flop 100 further comprises a data retention unit 104. In this embodiment, the data retention unit 104 comprises a PMOS transistor 104P and a NMOS transistor 104N connected in parallel and connected between the first node S0 and the second node S1. Specifically, a source terminal of the PMOS transistor 104P and a drain terminal of the NMOS transistor 104N are connected in parallel and electrically connected to the second node S1, a drain terminal of the PMOS transistor 104P and a source terminal of the NMOS transistor 104N are connected in parallel and electrically connected to the first node S0, a gate terminal of the PMOS transistor 104P is electrically connected to a power supply VDD, and a gate terminal of the NMOS transistor 104N is electrically connected to a ground VSS.

Since the gate terminal of the PMOS transistor 104P in the data retention unit 104 is electrically connected to the power supply VDD, and the gate terminal of the NMOS transistor 104N is electrically connected to the ground VSS, under driving of a high level signal of the power supply VDD, the PMOS transistor 104P is in a turn-off state, and under driving of a low level signal of the ground VSS, the NMOS transistor 104N is also in a turn-off state. At this time, the data retention unit 104 is equivalent to a capacitor for assisting in storing data latched at the first node S0, extending the retention time of data, improving stability of data storage, and thereby enhancing data security and accuracy.

It shall be noted that in the invention, the PMOS transistor 104P and the NMOS transistor 104N in the data retention unit 104 may together serve as the data retention unit 104, and also may separately serve as the data retention unit 104. In other words, the data retention unit 104 may comprise the PMOS transistor 104P and the NMOS transistor 104N, and also may comprise the PMOS transistor 104P or the NMOS transistor 104N only, but the invention is not limited thereto.

As an example:

The PMOS transistor 104P has a source terminal electrically connected to the first node or the second node, a drain terminal electrically connected to the second node or the first node, and a gate terminal electrically connected to a power supply.

The NMOS transistor 104N has a source terminal electrically connected to the first node or the second node, a drain terminal electrically connected to the second node or the first node, and a gate terminal electrically connected to a ground.

### Embodiment Two

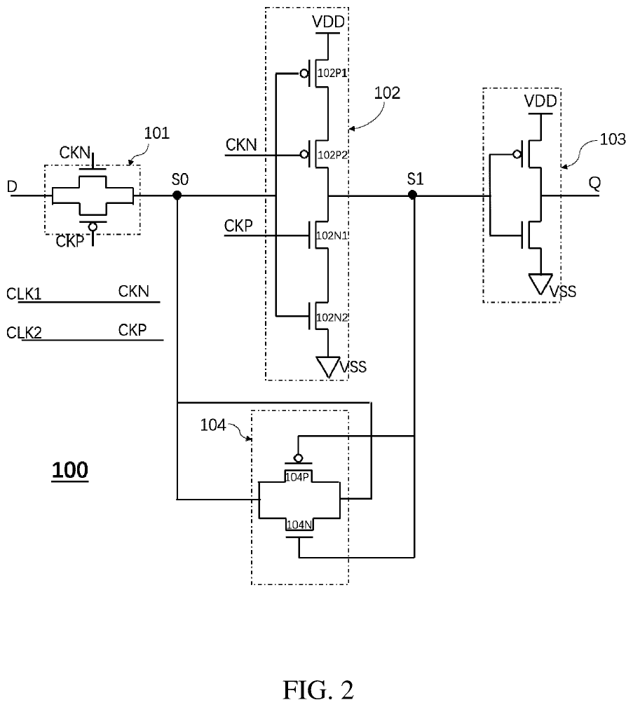

FIG. 2 is a schematic diagram of a circuit of a dynamic D flip-flop in another embodiment of the invention. The dynamic D flip-flop 100 shown in FIG. 2 differs from the embodiment shown in FIG. 1 in the structure of the data retention unit 104. As shown in FIG. 2, in this embodiment, the data retention unit 104 comprises a PMOS transistor 104P and a NMOS transistor 104N connected in parallel, a source terminal of the PMOS transistor 104P is electrically connected to a source terminal of the NMOS transistor 104N and electrically connected to the first node S0, a drain terminal of the PMOS transistor 104P is electrically connected to a drain terminal of the NMOS transistor 104N and electrically connected to the first node S0, and a gate terminal of the PMOS transistor 104P and a gate terminal of the NMOS transistor 104N are connected together and electrically connected to the second node S1.

Similarly, the PMOS transistor 104P and the NMOS transistor 104N in the data retention unit 104 serve as a capacitor for assisting in storing data latched at the first node S0 and data transmitted to the second node S1, extending the retention time of data, improving stability of data storage, and thereby enhancing data security and accuracy.

It shall be noted that in the invention, the PMOS transistor 104P and the NMOS transistor 104N in the data retention unit 104 may together serve as the data retention unit 104, and also may separately serve as the data retention unit 104. In other words, the data retention unit 104 may comprise the PMOS transistor 104P and the NMOS transistor 104N, and also may comprise the PMOS transistor 104P or the NMOS transistor 104N only, but the invention is not limited thereto.

As an example:

The PMOS transistor 104P has a source terminal, a drain terminal and a gate terminal, the source terminal and the drain terminal of the PMOS transistor 104P are electrically connected to the first node or the second node, and the gate terminal of the PMOS transistor 104P is electrically connected to the second node or the first node.

The NMOS transistor 104N has a source terminal, a drain terminal and a gate terminal, the source terminal and the drain terminal of the NMOS transistor 104N are electrically connected to the first node or the second node, and the gate terminal of the NMOS transistor 104N is electrically connected to the second node or the first node.

### Variable Embodiment

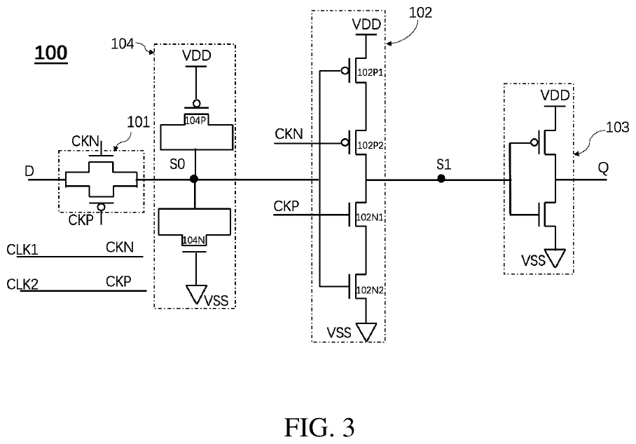

FIG. 3 is a schematic diagram of a circuit of a dynamic D flip-flop in still another embodiment of the invention. Difference from the embodiment shown in FIG. 1 is that in this embodiment, the data retention unit 104 is only electrically connected to the first node S0.

As shown in FIG. 3, in this embodiment, a source terminal and a drain terminal of a PMOS transistor 104P are connected in parallel and electrically connected to the first node S0, and a gate terminal of the PMOS transistor 104P is electrically connected to a power supply VDD. A source terminal and a drain terminal of a NMOS transistor 104N are connected in parallel and electrically connected to the first node S0, and a gate terminal of the NMOS transistor 104N is electrically connected to a ground VSS.

Similarly, the PMOS transistor 104P and the NMOS transistor 104N in the data retention unit 104 serve as a capacitor respectively for assisting in storing data latched at the first node S0, extending the retention time of data, improving stability of data storage, and thereby enhancing data security and accuracy.

It shall be noted that in the invention, the PMOS transistor 104P and the NMOS transistor 104N in the data retention unit 104 may together serve as the data retention unit 104, and also may separately serve as the data retention unit 104. In other words, the data retention unit 104 may comprise the PMOS transistor 104P and the NMOS transistor 104N, and also may comprise the PMOS transistor 104P or the NMOS transistor 104N only, but the invention is not limited thereto.

Of course, the data retention unit 104 may be disposed at the first node S0, and also may be disposed at the second node S1. Alternatively, the data retention units 104 are disposed at both the first node S0 and the second node S1, but the invention is not limited thereto.

As an example:

The PMOS transistor 104P has a source terminal, a drain terminal and a gate terminal, the source terminal and the drain terminal of the PMOS transistor 104P are electrically connected to the first node, and the gate terminal of the PMOS transistor 104P is electrically connected to a power supply.

The NMOS transistor 104N has a source terminal, a drain terminal and a gate terminal, the source terminal and the drain terminal of the NMOS transistor 104N are electrically connected to the first node, and the gate terminal of the NMOS transistor 104N is electrically connected to a ground.

The PMOS transistor 104P has a source terminal, a drain terminal and a gate terminal, the source terminal and the drain terminal of the PMOS transistor 104P are electrically connected to the second node, and the gate terminal of the PMOS transistor 104P is electrically connected to a power supply.

The NMOS transistor 104N has a source terminal, a drain terminal and a gate terminal, the source terminal and the drain terminal of the NMOS transistor 104N are electrically connected to the second node, and the gate terminal of the NMOS transistor 104N is electrically connected to a ground.

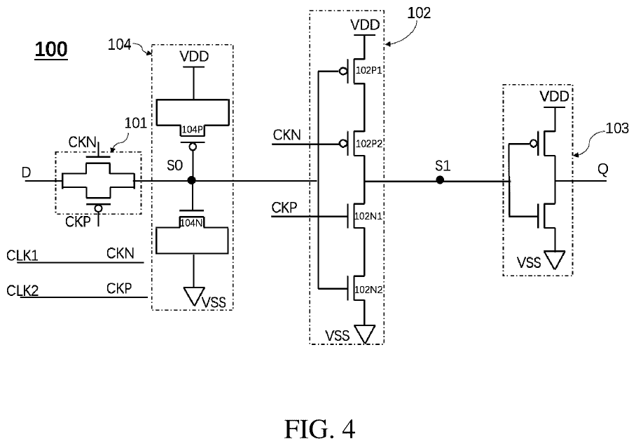

FIG. 4 is a schematic diagram of a circuit of a dynamic D flip-flop in yet another embodiment of the invention. Difference from the embodiment shown in FIG. 3 is that the connection method of the data retention unit 104 is different. As shown in FIG. 4, in this embodiment, a source terminal and a drain terminal of the PMOS transistor 104P are connected in parallel and electrically connected to the power supply VDD, and a gate terminal of the PMOS transistor 104P is electrically connected to the first node S0. A source terminal and a drain terminal of the NMOS transistor 104N are connected in parallel and electrically connected to the ground VSS, and a gate terminal of the NMOS transistor 104N is electrically connected to the first node S0.

Similarly, the PMOS transistor 104P and the NMOS transistor 104N in the data retention unit 104 serve as a capacitor for assisting in storing data latched at the first node S0, extending the retention time of data, improving stability of data storage, and thereby enhancing data security and accuracy.

It shall be noted that in the invention, the PMOS transistor 104P and the NMOS transistor 104N in the data retention unit 104 may together serve as the data retention unit 104, and also may separately serve as the data retention unit 104. In other words, the data retention unit 104 may comprise the PMOS transistor 104P and the NMOS transistor 104N, and also may comprise the PMOS transistor 104P or the NMOS transistor 104N only, but the invention is not limited thereto.

Of course, the data retention unit 104 may be disposed at the first node S0, and also may be disposed at the second node S1. Alternatively, the data retention units 104 are disposed at both the first node S0 and the second node S1, but the invention is not limited thereto.

As an example:

The PMOS transistor 104P has a source terminal, a drain terminal and a gate terminal, the source terminal and the drain terminal of the PMOS transistor 104P are electrically connected to a power supply, and the gate terminal of the PMOS transistor 104P is electrically connected to the first node.

The NMOS transistor 104N has a source terminal, a drain terminal and a gate terminal, the source terminal and the drain terminal of the NMOS transistor 104N are electrically connected to a ground, and the gate terminal of the NMOS transistor 104N is electrically connected to the first node.

The PMOS transistor 104P has a source terminal, a drain terminal and a gate terminal, the source terminal and the drain terminal of the PMOS transistor 104P are electrically connected to a power supply, and the gate terminal of the PMOS transistor 104P is electrically connected to the second node.

The NMOS transistor 104N has a source terminal, a drain terminal and a gate terminal, the source terminal and the drain terminal of the NMOS transistor 104N are electrically connected to a ground, and the gate terminal of the NMOS transistor 104N is electrically connected to the second node.

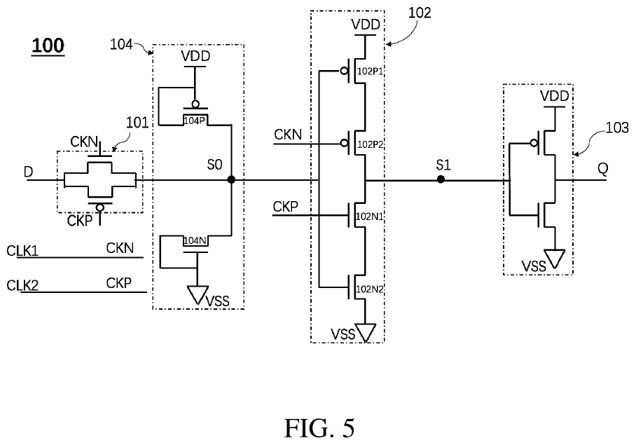

FIG. 5 is a schematic diagram of a circuit of a dynamic D flip-flop in an extended embodiment of the invention. Difference from the embodiments shown in FIGS. 3 and 4 is that the connection method of the data retention unit 104 is different. As shown in FIG. 5, in this embodiment, a source terminal and a gate terminal of the PMOS transistor 104P are connected in parallel and electrically connected to the power supply VDD, and a drain terminal of the PMOS transistor 104P is electrically connected to the first node S0. A source terminal and a gate terminal of the NMOS transistor 104N are connected in parallel and electrically connected to the ground VSS, and a drain terminal of the NMOS transistor 104N is electrically connected to the first node S0.

Similarly, the PMOS transistor 104P and the NMOS transistor 104N in the data retention unit 104 serve as a capacitor for assisting in storing data latched at the first node S0, extending the retention time of data, improving stability of data storage, and thereby enhancing data security and accuracy.

It shall be noted that in the invention, the PMOS transistor 104P and the NMOS transistor 104N in the data retention unit 104 may together serve as the data retention unit 104, and also may separately serve as the data retention unit 104. In other words, the data retention unit 104 may comprise the PMOS transistor 104P and the NMOS transistor 104N, and also may comprise the PMOS transistor 104P or the NMOS transistor 104N only, but the invention is not limited thereto.

Of course, the data retention unit 104 may be disposed at the first node S0, and also may be disposed at the second node S1. Alternatively, the data retention units 104 are disposed at both the first node S0 and the second node S1, but the invention is not limited thereto.

As an example:

The PMOS transistor 104P has a source terminal, a drain terminal and a gate terminal, the source terminal (or the drain terminal) and the gate terminal of the PMOS transistor 104P are electrically connected to a power supply, and the drain terminal (or the source terminal) of the PMOS transistor 104P is electrically connected to the first node.

The NMOS transistor 104N has a source terminal, a drain terminal and a gate terminal, the source terminal (or the drain terminal) and the gate terminal of the NMOS transistor 104N are electrically connected to a ground, and the drain terminal (or the source terminal) of the NMOS transistor 104N is electrically connected to the first node.

The PMOS transistor 104P has a source terminal, a drain terminal and a gate terminal, the source terminal (or the drain terminal) and the gate terminal of the PMOS transistor 104P are electrically connected to a power supply, and the drain terminal (or the source terminal) of the PMOS transistor 104P is electrically connected to the second node.

The NMOS transistor 104N has a source terminal, a drain terminal and a gate terminal, the source terminal (or the drain terminal) and the gate terminal of the NMOS transistor 104N are electrically connected to a ground, and the drain terminal (or the source terminal) of the NMOS transistor 104N is electrically connected to the second node.

In the above embodiments, one connection method of the PMOS transistor and NMOS transistor is used for illustration, and the source terminal and drain terminal of the PMOS transistor and the NMOS transistor may be interchanged, but the invention is not limited thereto.

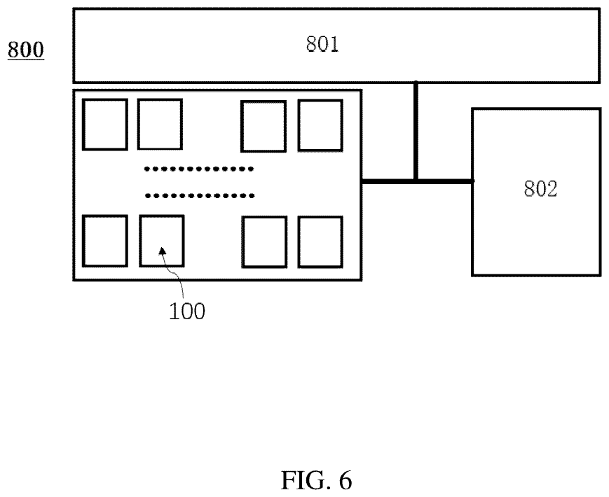

The invention further provides a data operation unit, and FIG. 6 is a schematic diagram of a data operation unit of the invention. As shown in FIG. 6, the data operation unit 800 comprises a control circuit 801, an operational circuit 802 and a plurality of dynamic D flip-flops 100, and the plurality of dynamic D flip-flops 100 are connected in series or in parallel. The control circuit 801 refreshes the data in the dynamic D flip-flops 100 and reads the data from the dynamic D flip-flops 100, the operational circuit 802 performs operation on the read data, and then an operation result is outputted by the control circuit 801.

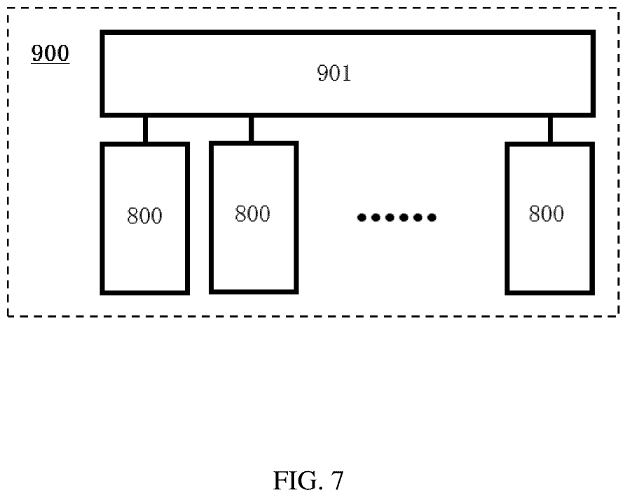

The invention further provides a chip, and FIG. 7 is a schematic diagram of a chip of the invention. As shown in FIG. 7, the chip 900 comprises a control unit 901 and one or more data operation units 800. The control unit 901 inputs data to the data operation units 800 and processes the data outputted from the data operation units 800.

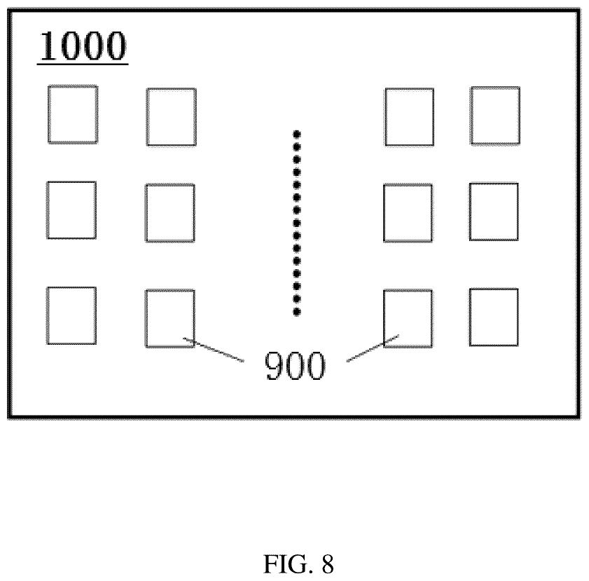

The invention further provides a hash board, and FIG. 8 is a schematic diagram of a hash board of the invention. As shown in FIG. 8, each hash board 1000 comprises one or more chips 900, which perform large-scale operations on working data sent downstream from the computing device.

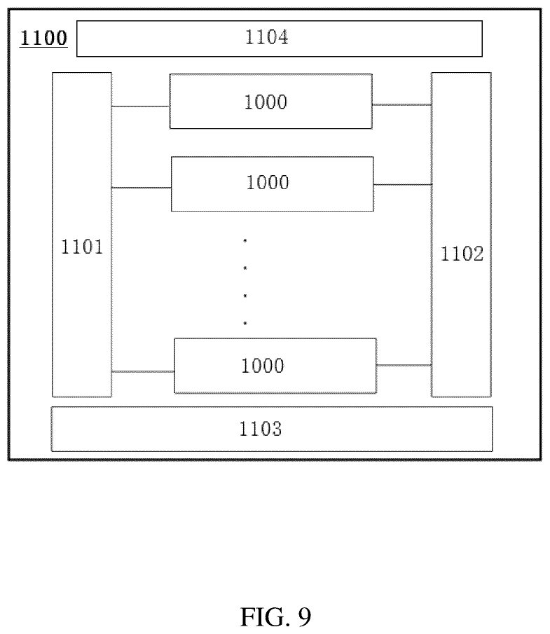

The invention further provides a computing device, which is preferably configured to operation of mining virtual digital currency, and of course, the computing device also may be configured to any other massive operations. FIG. 9 is a schematic diagram of a computing device of the invention. As shown in FIG. 9, each computing device 1100 comprises a connection board 1101, a control board 1102, a radiator 1103, a power supply board 1104 and one or more hash boards 1000. The control board 1102 is connected to the hash boards 1000 through the connection board 1101, and the radiator 1103 is disposed around the hash boards 1000. The power supply board 1104 is configured to supply a power supply to the connection board 1101, the control board 1102, the radiator 1103 and the hash boards 1000.

It shall be noted that in the description of the invention, the orientation or positional relationship indicated by terms “transverse”, “longitudinal”, “up”, “down”, “front”, “back”, “left”, “right”, “vertical”, “horizontal”, “top”, “bottom”, “in”, “out”, and the like is an orientation or positional relationship illustrated by the drawings, and is only for the purpose of describing the invention and simplifying the explanation, rather than indicating or suggesting that the referred device or element must have the specific orientation, or being constructed and operated in the specific orientation, therefore shall not be understood as limit to the invention.

In other words, the invention may further have various other embodiments, and those skilled in the art shall make various corresponding modifications and variations according to the invention without departing from concept and essence of the invention, but these corresponding modifications and variations shall belong to the scope protected by the appended claims of the invention.

### INDUSTRIAL APPLICABILITY

Application of the dynamic D flip-flop in the invention has the following advantageous effects:

The dynamic D flip-flop provided by the invention can assist in storing data latched at the node, extending the retention time of data, improving stability of data storage, and thereby enhancing data security and accuracy.

What is claimed is:

1. A dynamic D flip-flop, comprising:
an input terminal for inputting a first data;
an output terminal for outputting a second data;
a clock signal terminal for supplying a clock signal;
a first latch unit for transmitting a data at the input terminal and latching the first data under control of the clock signal;
a second latch unit for latching the data transmitted by the first latch unit; and
an output drive unit for outputting the data received from the second latch unit;
the first latch unit, the second latch unit, and the output drive unit are sequentially connected in series between the input terminal and the output terminal; and
a first node is provided between the first latch unit and the second latch unit, and a second node is provided between the second latch unit and the output drive unit;
wherein, further comprising a data retention unit electrically connected to the first node and/or the second node, the data retention unit is configured for assisting in storing the data latched at the first node and/or the second node.

2. The dynamic D flip-flop according to claim 1, wherein the data retention unit has a first terminal electrically connected to the first node, and a second terminal electrically connected to the second node.

3. The dynamic D flip-flop according to claim 2, wherein the data retention unit comprises a PMOS transistor and/or a NMOS transistor.

4. The dynamic D flip-flop according to claim 3, wherein the PMOS transistor comprises a source terminal electrically connected to the first node, a drain terminal electrically connected to the second node, and a gate terminal electrically connected to a power supply, and
the NMOS transistor comprises a source terminal electrically connected to the first node, a drain terminal electrically connected to the second node, and a gate terminal electrically connected to a ground.

5. The dynamic D flip-flop according to claim 3, wherein the PMOS transistor comprises a source terminal and a drain terminal that are electrically connected to the first node, and a gate terminal electrically connected to the second node, and
the NMOS transistor comprises a source terminal and a drain terminal that are electrically connected to the first node, electrically connected to the second node, and a gate terminal electrically connected to the second node.

6. The dynamic D flip-flop according to claim 1, wherein the data retention unit is electrically connected to the first node or the second node, and the data retention unit comprises a PMOS transistor and/or a NMOS transistor.

7. The dynamic D flip-flop according to claim 6, wherein the PMOS transistor has a source terminal, a drain terminal and a gate terminal, the source terminal and the drain terminal of the PMOS transistor are electrically connected to the first node, and the gate terminal of the PMOS transistor is electrically connected to a power supply.

8. The dynamic D flip-flop according to claim 6, wherein the NMOS transistor has a source terminal, a drain terminal and a gate terminal, the source terminal and the drain terminal of the NMOS transistor are electrically connected to the first node, and the gate terminal of the NMOS transistor is electrically connected to a ground.

9. The dynamic D flip-flop according to claim 6, wherein the PMOS transistor has a source terminal, a drain terminal and a gate terminal, the source terminal and the drain terminal of the PMOS transistor are electrically connected to a power supply, and the gate terminal of the PMOS transistor is electrically connected to the first node.

10. The dynamic D flip-flop according to claim 6, wherein the NMOS transistor has a source terminal, a drain terminal and a gate terminal, the source terminal and the drain terminal of the NMOS transistor are electrically connected to a ground, and the gate terminal of the NMOS transistor is electrically connected to the first node.

11. The dynamic D flip-flop according to claim 6, wherein the PMOS transistor has a source terminal, a drain terminal and a gate terminal, the source terminal and the gate terminal of the PMOS transistor are electrically connected to a power supply, and the drain terminal of the PMOS transistor is electrically connected to the first node.

12. The dynamic D flip-flop according to claim 6, wherein the NMOS transistor has a source terminal, a drain terminal and a gate terminal, the source terminal and the gate terminal of the NMOS transistor are electrically connected to a ground, and the drain terminal of the NMOS transistor is electrically connected to the first node.

13. The dynamic D flip-flop according to claim 6, wherein the PMOS transistor has a source terminal, a drain terminal and a gate terminal, the source terminal and the drain terminal of the PMOS transistor are electrically connected to the second node, and the gate terminal of the PMOS transistor is electrically connected to a power supply.

14. The dynamic D flip-flop according to claim 6, wherein the NMOS transistor has a source terminal, a drain terminal and a gate terminal, the source terminal and the drain terminal of the NMOS transistor are electrically connected to the second node, and the gate terminal of the NMOS transistor is electrically connected to a ground.

15. The dynamic D flip-flop according to claim 6, wherein the PMOS transistor has a source terminal, a drain terminal and a gate terminal, the source terminal and the drain terminal of the PMOS transistor are electrically connected to a power supply, and the gate terminal of the PMOS transistor is electrically connected to the second node.

16. The dynamic D flip-flop according to claim 6, wherein the NMOS transistor has a source terminal, a drain terminal and a gate terminal, the source terminal and the drain terminal of the NMOS transistor are electrically connected to a ground, and the gate terminal of the NMOS transistor is electrically connected to the second node.

17. The dynamic D flip-flop according to claim 6, wherein the PMOS transistor has a source terminal, a drain terminal and a gate terminal, the source terminal and the gate terminal of the PMOS transistor are electrically connected to a power supply, and the drain terminal of the PMOS transistor is electrically connected to the second node.

18. The dynamic D flip-flop according to claim 6, wherein the NMOS transistor has a source terminal, a drain terminal and a gate terminal, the source terminal and the gate terminal of the NMOS transistor are electrically connected to a ground, and the drain terminal of the NMOS transistor is electrically connected to the second node.

19. The dynamic D flip-flop according to claim 1, wherein the clock signal comprises a first clock signal and a second clock signal in an opposite phase.

20. The dynamic D flip-flop according to claim 19, wherein the first latch unit is a transmission gate.

21. The dynamic D flip-flop according to claim 20, wherein the transmission gate comprises a PMOS transistor and a NMOS transistor connected in parallel, a gate terminal of the PMOS transistor is electrically connected to the first clock signal, and a gate terminal of the NMOS transistor is electrically connected to the second clock signal.

22. The dynamic D flip-flop according to claim 19, wherein the second latch unit is a three-state inverter.

23. The dynamic D flip-flop according to claim 22, wherein the three-state inverter comprises a first PMOS transistor, a second PMOS transistor, a first NMOS transistor and a second NMOS transistor connected in series, gate terminals of the first PMOS transistor and the second NMOS transistor are electrically connected as an input terminal of the three-state inverter, a gate terminal of the second PMOS transistor is electrically connected to the second clock signal, and a gate terminal of the first NMOS transistor is electrically connected to the first clock signal.

24. The dynamic D flip-flop according to claim 1, wherein the output drive unit is an inverter.

25. The dynamic D flip-flop according to claim 24, wherein the inverter comprises a PMOS transistor and a NMOS transistor connected in series.

26. A data operation unit, comprising a control circuit, an operational circuit and a plurality of dynamic D flip-flops interconnected with each other, the plurality of dynamic D flip-flops are connected in series and/or in parallel; wherein, the plurality of dynamic D flip-flops are the dynamic D flip-flop according to claim 1.

27. A chip, comprising a data operation unit, wherein the data operation unit comprises a control circuit, an operational circuit and a plurality of dynamic D flip-flops interconnected with each other, the plurality of dynamic D flip-flops are connected in series and/or in parallel; wherein, the plurality of dynamic D flip-flops are the dynamic D flip-flop according to claim 1.
